(19) United States
(12) Patent Application Publication
(10) Pub. No.: US 2026/0173774 A1
(43) Pub. Date: Jun. 18, 2026

(54) FERROELECTRIC GATE STACK, FERROELECTRIC FIELD EFFECT TRANSISTOR, AND METHOD OF MANUFACTURING FERROELECTRIC GATE STACK

(71) Applicants: INSTITUTE OF MICROELECTRONICS, CHINESE ACADEMY OF SCIENCES, Beijing (CN); Guangdong Greater Bay Area Institute of Integrated Circuit and System, Guangzhou, Guangdong (CN)

(72) Inventors: Jun LUO, Beijing (CN); Bohan CHEN, Beijing (CN); Jing XU, Beijing (CN)

(21) Appl. No.: 18/721,269

(22) PCT Filed: Apr. 22, 2024
(86) PCT No.: PCT/CN2024/089144

§ 371 Date: Jun. 18, 2024

(30) Foreign Application Priority Data
Apr. 23, 2023 (CN) 202310440684.6

(51) Int. Cl. H10N 70/00; H10D 30/01; H10D 30/69; H10D 64/68

(52) U.S. Cl. CPC H10N 70/841; H10D 30/0415; H10D 30/701; H10D 64/685; H10D 64/689; H10D 64/691; H10D 64/693; H10N 70/021; H10N 70/823; H10N 70/8833

(57) ABSTRACT

The present disclosure relates to a ferroelectric gate stack, a ferroelectric field effect transistor, and a method of manufacturing a ferroelectric gate stack, which pertain to the field of microelectronic technology. The ferroelectric gate stack includes a gate oxygen layer, a thin dielectric layer, and a further gate dielectric layer sequentially stacked from bottom to top; a ferroelectric layer is further provided between the thin dielectric layer and the gate oxygen layer, and a resistive switching layer is further provided between the thin dielectric layer and the further gate dielectric layer; or a resistive switching layer is further provided between the thin dielectric layer and the gate oxygen layer, and a ferroelectric layer is further provided between the thin dielectric layer and the further gate dielectric layer.

### CROSS REFERENCE TO RELATED APPLICATION

This application is a National Stage Application of International Application No. PCT/CN2024/089144, filed on Apr. 22, 2024, entitled “FERROELECTRIC GATE STACK, FERROELECTRIC FIELD EFFECT TRANSISTOR, AND METHOD OF MANUFACTURING FERROELECTRIC GATE STACK”, which claims priority to Chinese Patent Application No. 202310440684.6 filed on Apr. 23, 2023, which is incorporated herein by reference in its entirety.

### TECHNICAL FIELD

The present disclosure relates to the field of microelectronic technology, in particular to a ferroelectric gate stack, a ferroelectric field effect transistor, and a method of manufacturing a ferroelectric gate stack.

### BACKGROUND

With the advent of the era of big data, people have increasing demands for high-performance memories. Traditional non-volatile FLASH memory structures are facing challenges, and new memory structures need to be developed. At present, the most competitive non-volatile memories include FLASH, FeRAM, MRAM, PCM, and RRAM. 1T1C or 1T1R is generally used to construct the architecture of memory. The FLASH memory requires a large write voltage and may be rewritten for a low number of times. In the four emerging devices, only FeRAM, PCM and RRAM may achieve an electric field control, where in FeRAM, a polarization is generated due to a change of voltage applied at both ends; in PCM, a phase change is generated due to Joule heating generated by current; and in RRAM, a resistive switching is generated by a control of voltage at both ends.

A ferroelectric storage technology may be combined with a transistor to form a ferroelectric transistor (FeFET) structure, so that a single transistor may complete storage of information, and it may be expected to store information in a smaller unit. However, for hafnium-oxide-based FeFET, a ferroelectric layer may undergo an undesired switching under multiple excitations of, for example, crosstalk of surrounding electric field which is slightly lower than a coercive electric field, so that the transistor may be turned on abnormally to result in a loss of information. This is referred to as accumulation switching of the ferroelectric layer.

### SUMMARY

The embodiments of the present disclosure are intended to provide a ferroelectric gate stack, a ferroelectric field effect transistor, and a method of manufacturing a ferroelectric gate stack.

In a first aspect, the present disclosure provides a ferroelectric gate stack, which includes a gate oxygen layer, a thin dielectric layer, and a further gate dielectric layer sequentially stacked from bottom to top; where a ferroelectric layer is further provided between the thin dielectric layer and the gate oxygen layer, and a resistive switching layer is further provided between the thin dielectric layer and the further gate dielectric layer; or a resistive switching layer is further provided between the thin dielectric layer and the gate oxygen layer, and a ferroelectric layer is further provided between the thin dielectric layer and the further gate dielectric layer.

Further, a material of the resistive switching layer includes one or more of hafnium oxide, silicon oxide, zinc oxide or copper oxide, and a thickness of the resistive switching layer is in a range of 5 nm to 25 nm.

Further, a material of the gate oxygen layer includes silicon oxide or silicon nitride.

Further, a thickness of the gate oxygen layer is in a range of 0 nm to 20 nm.

Further, a material of the thin dielectric layer includes alumina.

Further, a thickness of the thin dielectric layer is in a range of 1 nm to 5 nm.

Further, the ferroelectric layer contains HZO, in which a molar ratio of hafnium oxide to zirconia is in a range of 4:1 to 1:2, and a thickness of the ferroelectric layer is in a range of 5 nm to 15 nm.

In a second aspect, the present disclosure provides a ferroelectric field effect transistor, including the above-mentioned ferroelectric gate stack.

Further, the ferroelectric field effect transistor includes a bulk silicon planar transistor, a silicon-on-insulator transistor, a fin transistor, or a gate-all-around transistor.

In another aspect, the present disclosure provides a method of manufacturing the ferroelectric gate stack, including: step (1) of providing a substrate and preparing the gate oxygen layer on the substrate; step (2) of preparing the ferroelectric layer or the resistive switching layer on the gate oxygen layer; step (3) of preparing the thin dielectric layer on the ferroelectric layer or the resistive switching layer prepared in the step (2); step (4) of preparing the resistive switching layer or the ferroelectric layer on the thin dielectric layer; and step (5) of preparing the further gate dielectric layer on the resistive switching layer or the ferroelectric layer prepared in the step (4); where a layer above the thin dielectric layer and a layer below the thin dielectric layer are not simultaneously selected to be ferroelectric layers or not simultaneously selected to be resistive switching layers.

In the present disclosure, the above-mentioned technical solutions may also be combined with each other to achieve more preferred combined solutions. Other features and advantages of the present disclosure will be set forth in the following description, and some of the advantages may become apparent from the description or may be understood through the implementation of the present disclosure. Objectives and other advantages of the present disclosure may be achieved and obtained by means of the contents specified in the description and the accompanying drawings.

### BRIEF DESCRIPTION OF THE DRAWINGS

The accompanying drawings are used only for the purpose of illustrating specific embodiments and should not be considered as limitations to the present disclosure. Throughout the accompanying drawings, the same reference numerals represent the same components.

FIG. 1 shows a schematic structural diagram of a ferroelectric gate stack provided in the present disclosure;

FIG. 2 shows a schematic structural diagram of another ferroelectric gate stack provided in the present disclosure;

FIG. 3 shows a schematic structural diagram of another ferroelectric gate stack provided in the present disclosure; and

FIG. 4 shows a schematic structural diagram of an NMOS device provided in the present disclosure.

In the accompanying drawings: 1—gate oxygen layer, 2—ferroelectric layer, 3—thin dielectric layer, 4—resistive switching layer, 5—metal work function layer, 6—contact metal layer, 7—substrate, 8—source electrode, 9—drain electrode, 10—further gate dielectric layer, 11—ferroelectric gate stack, 12—silicon oxide layer, 13—silicon nitride layer.

### DETAILED DESCRIPTION OF EMBODIMENTS

The preferred embodiments of the present disclosure will be described below in conjunction with the accompanying drawings. The accompanying drawings constitute part of the present disclosure and are used together with the embodiments of the present disclosure to illustrate the principle of the present disclosure, rather than to limit the scope of the present disclosure.

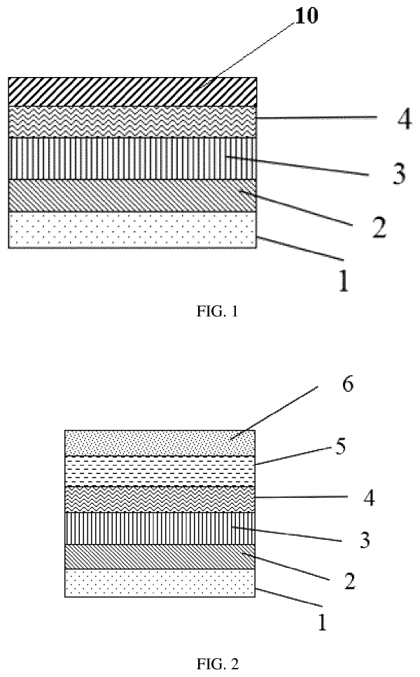

In a specific embodiment of the present disclosure, as shown in FIG. 1, a ferroelectric gate stack is provided, which includes a gate oxygen layer 1, a thin dielectric layer 3 and a further gate dielectric layer 10 sequentially stacked from bottom to top. A ferroelectric layer 2 is further provided between the thin dielectric layer 3 and the gate oxygen layer 1, and a resistive switching layer 4 is further provided between the thin dielectric layer 3 and the further gate dielectric layer. Alternatively, a resistive switching layer 4 is further provided between the thin dielectric layer 3 and the gate oxygen layer 1, and a ferroelectric layer 2 is further provided between the thin dielectric layer 3 and the further gate dielectric layer.

Different from the related art, in the ferroelectric field effect transistor provided in the embodiment, a resistive switching layer 4 is stacked on the gate. In a case of a voltage lower than a coercive voltage, the greater the voltage applied, the more obvious the accumulation switching of the ferroelectric layer, and the ferroelectric layer may undergo undesired switching under influence of surrounding crosstalk. The greater the crosstalk, the faster the undesired switching occurs, while the smaller the crosstalk, the slower the undesired switching occurs. In the present disclosure, the resistive switching layer 4 is added, of which a resistance may decrease when a critical voltage (which is set to be greater than the coercive voltage of the ferroelectric layer) arrives. The resistive switching layer 4 is connected in series to the ferroelectric layer 2. Before the arrival of the critical voltage, the resistance of the resistive switching layer 4 may increase to share more voltage, and the crosstalk on the ferroelectric layer 2 may be reduced. After the arrival of the critical voltage, the resistive switching layer 4 may share less voltage, and most of the voltage may be applied to the ferroelectric layer 2. When the voltage on the ferroelectric layer 2 is less than the coercive voltage, no accumulation switching may be caused by surrounding crosstalk. Therefore, when the ferroelectric layer 2 reaches a desired coercive voltage, the transistor may be turned on normally, and the resistive switching layer may weaken the accumulation switching.

It should be noted that the resistive switching layer 4 and the ferroelectric layer 2 of the present disclosure may be arbitrarily provided above or below the thin dielectric layer, and either may achieve the above-mentioned function.

The further gate dielectric layer of the present disclosure may adopt the structure in the related art. For example, as shown in FIG. 2 to FIG. 4, the further gate dielectric layer may include a metal work function layer 5 and a contact metal layer 6 from bottom to top. The metal work function layer 5 contains 5 nm TiN and 5 nm TiAl, and the contact metal layer 6 is made of tungsten.

In a specific embodiment of the present disclosure, as shown in FIG. 2, a ferroelectric gate stack is provided, which includes a gate oxygen layer 1, a ferroelectric layer 2, a thin dielectric layer 3, a resistive switching layer 4, a metal work function layer 5 and a contact metal layer 6 sequentially stacked from bottom to top.

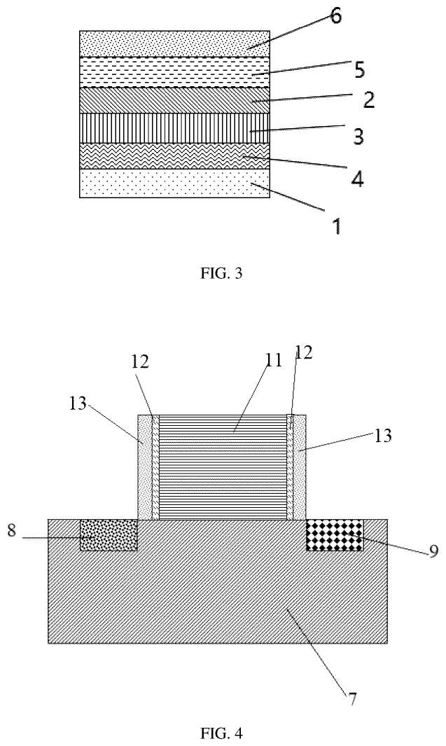

In another specific embodiment of the present disclosure, as shown in FIG. 3, a ferroelectric gate stack is provided, which includes a gate oxygen layer 1, a resistive switching layer 4, a thin dielectric layer 3, a ferroelectric layer 2, a metal work function layer 5 and a contact metal layer 6 sequentially stacked from bottom to top.

Specifically, a material of the resistive switching layer 4 includes one or more of hafnium oxide, silicon oxide, zinc oxide, or copper oxide. A thickness of the resistive switching layer is in a range of 5 nm to 25 nm, such as 5 nm, 7 nm, 9 nm, 11 nm, 13 nm, 15 nm, 17 nm, 19 nm, 21 nm, 23 nm, or 25 nm.

It should be noted that when the resistive switching layer 4 is made of the above-mentioned materials, the resistance of the resistive switching layer 4 may decrease when the critical voltage (which is set to be greater than the coercive voltage of the ferroelectric layer) arrives. The resistive switching layer is connected in series to the ferroelectric layer. Before the arrival of the critical voltage, the resistance of the resistive switching layer 4 may increase to share more voltage, and the crosstalk on the ferroelectric layer 2 may be reduced. After the arrival of the critical voltage, the resistive switching layer 4 may share less voltage, and most of the voltage may be applied to the ferroelectric layer 2. When the voltage on the ferroelectric layer 2 is less than the coercive voltage, no accumulation switching may be caused by surrounding crosstalk. Therefore, when the ferroelectric layer 2 reaches a desired coercive voltage, the transistor may be turned on normally.

Specifically, the gate oxygen layer 1 is made of silicon oxide or silicon nitride.

Specifically, a thickness of the gate oxygen layer 1 is in a range of 0 nm to 20 nm, such as 0 nm, 2 nm, 4 nm, 6 nm, 8 nm, 10 nm, 12 nm, 14 nm, 16 nm, 18 nm or 20 nm.

It should be noted that the less the thickness of the gate oxygen layer 1, the better the gating effect of the device. In the present disclosure, the thickness of the gate oxygen layer 1 is selected to be in a range of 0 nm to 20 nm.

Specifically, the thin dielectric layer 3 is made of alumina.

Specifically, a thickness of the thin dielectric layer 3 is in a range of 1 nm to 5 nm, such as 1 nm, 2 nm, 3 nm, 4 nm or 5 nm.

Specifically, the ferroelectric layer 2 contains HZO, in which a molar ratio of hafnium oxide to zirconia is in a range of 4:1 to 1:2.

Specifically, a thickness of the ferroelectric layer 2 is in a range of 5 nm to 15 nm, such as 5 nm, 6 nm, 7 nm, 8 nm, 9 nm, 10 nm, 11 nm, 12 nm, 13 nm, 14 nm or 15 nm.

It should be noted that in a case of a too small thickness of the ferroelectric layer 2, the ferroelectric layer 2 may have a poor quality, while in a case of a too large thickness of the ferroelectric layer 2, ferroelectric characteristics of the ferroelectric layer 2 may not be obvious.

Specifically, the metal work function layer 5 may have an adjustable work function to adjust a threshold voltage of the transistor.

Specifically, the metal work function layer 5 is made of 5 nm TiN and 5 nm TiAl.

Specifically, the contact metal layer is made of tungsten, and has a thickness of 80 nm.

In another specific embodiment of the present disclosure, a ferroelectric field effect transistor is provided, which includes the above-mentioned ferroelectric gate stack.

Specifically, the ferroelectric field effect transistor includes a bulk silicon planar transistor, a silicon-on-insulator transistor, a fin transistor, or a gate-all-around transistor.

In another specific embodiment of the present disclosure, a method of manufacturing a ferroelectric gate stack is provided, which specifically includes the following steps.

In step (1), a substrate is provided, and a gate oxygen layer 1 is prepared on the substrate.

In step (2), a ferroelectric layer 2 or a resistive switching layer 4 is prepared on the gate oxygen layer 1.

In step (3), a thin dielectric layer 3 is prepared on the ferroelectric layer 2 or the resistive switching layer 4 prepared in the step (2).

In step (4), a resistive switching layer 4 or a ferroelectric layer 2 is prepared on the thin dielectric layer 3.

In step (5), a further gate dielectric layer 10 is prepared on the resistive switching layer 4 or the ferroelectric layer 2 prepared in the step (4).

A layer above the thin dielectric layer 3 and a layer below the thin dielectric layer 3 are not simultaneously selected to be ferroelectric layers 2 or not simultaneously selected to be resistive switching layers 4.

The method of manufacturing the ferroelectric gate stack in the present disclosure is simple, so that the ferroelectric gate stack may be manufactured easily and may be produced on a large scale.

It should be noted that the layer above the thin dielectric layer 3 and the layer below the thin dielectric layer 3 are not simultaneously to be ferroelectric layers 2 or not simultaneously to be resistive switching layers 4. The gate oxygen layer 1 is prepared on the substrate. The substrate may be made of a material in the related art, and may be a silicon substrate, a germanium substrate or an SOI substrate, etc. In the process of manufacturing the ferroelectric gate stack in the present disclosure, each layer is prepared using solutions in the related art. In the present disclosure, various layers may be formed by processes including but not limited to physical vapor deposition, chemical vapor deposition, evaporation, sputtering, etc., all of which are conventional technical means in the art and will not be described in detail in the present disclosure.

In a preferred specific embodiment, in step (2), the ferroelectric layer is prepared by atomic layer deposition (ALD), where a metal alkyl compound is selected for Zr-doped HfO₂ precursor, the precursor of Hf is tetrakis(ethylmethylamino) hafnium (Hf[N(C₂H₅)CH₃]₄, TEMAH), the precursor of Zr is tetrakis(ethylmethylamino) zirconium (Zr[N(C₂H₅)CH₃]₄, TEMAZ), and the precursor of oxygen is water vapor. A Zr-doped HfO₂ thin film is formed by ALD, where a growth temperature of 280° C. and a reaction chamber pressure of 2 mBar are recommended. A doping ratio of Hf and Zr is controlled by adjusting the number of alternating cycles of HfO₂ and ZrO₂. After the deposition is completed, a rapid thermal annealing process is performed, where a temperature rise time of 10 seconds, a set temperature of 500° C. and a holding time of 30 seconds are recommended.

In a preferred specific embodiment, in step (4), the resistive switching layer 4 is prepared by ALD, where a growth temperature is 300° C.

The technical solutions of the present disclosure will be further described below with reference to specific examples.

### Example 1

As shown in FIG. 2, the present disclosure provides a ferroelectric gate stack, which includes a gate oxygen layer 1, a ferroelectric layer 2, a thin dielectric layer 3, a resistive switching layer 4, a metal work function layer 5 and a contact metal layer 6 sequentially stacked from bottom to top.

The gate oxygen layer 1 has a thickness of 20 nm and is made of silicon oxide; the ferroelectric layer 2 has a thickness of 5 nm, and a molar ratio of hafnium oxide to zirconia is 1:1; the thin dielectric layer 3 has a thickness of 1 nm and is made of alumina; the resistive switching layer 4 has a thickness of 5 nm and is made of hafnium oxide; the metal work function layer 5 is made of 5 nm TiN and 5 nm TiAl; and the contact metal layer 6 is made of tungsten and has a thickness of 80 nm. The ferroelectric gate stack in this example is manufactured by the following steps.

In step (1), a gate oxygen layer 1 is formed on a substrate by ALD.

In step (2), a ferroelectric layer 2 is formed on the gate oxygen layer 1 by ALD. Specifically, a Zr-doped HfO₂ thin film is formed by ALD, where a growth temperature of 280° C. and a reaction chamber pressure of 2 mBar are recommended. After the deposition is completed, a rapid thermal annealing process is performed, where a temperature rise time of 10 seconds, a set temperature of 500° C. and a holding time of 30 seconds are recommended.

In step (3), a thin dielectric layer 3 is formed on the ferroelectric layer 2 by ALD.

In step (4), a resistive switching layer 4 is formed on the thin dielectric layer 3 by ALD, where a growth temperature is 300° C.

In step (5), a metal work function layer 5 is formed on the resistive switching layer 4.

In step (6), a contact metal layer 6 is formed on the metal work function layer 5 and etched with a pattern, so as to obtain the ferroelectric gate stack.

### Example 2

As shown in FIG. 2, the present disclosure provides a ferroelectric gate stack, which includes a gate oxygen layer 1, a ferroelectric layer 2, a thin dielectric layer 3, a resistive switching layer 4, a metal work function layer 5 and a contact metal layer 6 sequentially stacked from bottom to top.

The gate oxygen layer 1 has a thickness of 10 nm and is made of silicon nitride; the ferroelectric layer 2 has a thickness of 10 nm, and a molar ratio of hafnium oxide to zirconia is 1:1; the thin dielectric layer 3 has a thickness of 3 nm and is made of alumina; the resistive switching layer 4 has a thickness of 10 nm and is made of zirconia; the metal work function layer 5 is made of 5 nm TiN and 5 nm TiAl; and the contact metal layer 6 is made of tungsten and has a thickness of 80 nm.

The method of manufacturing the ferroelectric gate stack in this example is the same as that in Example 1.

### Example 3

As shown in FIG. 2, the present disclosure provides a ferroelectric gate stack, which includes a gate oxygen layer 1, a ferroelectric layer 2, a thin dielectric layer 3, a resistive switching layer 4, a metal work function layer 5 and a contact metal layer 6 sequentially stacked from bottom to top.

The gate oxygen layer 1 has a thickness of 1 nm and is made of silicon oxide; the ferroelectric layer 2 has a thickness of 15 nm, and a molar ratio of hafnium oxide to zirconia is 1:1; the thin dielectric layer 3 has a thickness of 5 nm and is made of alumina; the resistive switching layer 4 has a thickness of 25 nm and is made of copper oxide; the metal work function layer 5 is made of 5 nm TiN and 5 nm TiAl; and the contact metal layer 6 is made of tungsten and has a thickness of 80 nm.

The method of manufacturing the ferroelectric gate stack in this example is the same as that in Example 1.

### Example 4

As shown in FIG. 2, the present disclosure provides a ferroelectric gate stack, which includes a gate oxygen layer 1, a ferroelectric layer 2, a thin dielectric layer 3, a resistive switching layer 4, a metal work function layer 5 and a contact metal layer 6 sequentially stacked from bottom to top.

The gate oxygen layer 1 has a thickness of 15 nm and is made of silicon oxide; the ferroelectric layer 2 has a thickness of 12 nm, and a molar ratio of hafnium oxide to zirconia is 1:1; the thin dielectric layer 3 has a thickness of 4 nm and is made of alumina; the resistive switching layer 4 has a thickness of 20 nm and is made of zinc oxide; the metal work function layer 5 is made of 5 nm TiN and 5 nm TiAl; and the contact metal layer 6 is made of tungsten and has a thickness of 80 nm. The method of manufacturing the ferroelectric gate stack in this example is the same as that in Example 1.

### Example 5

As shown in FIG. 3, the ferroelectric gate stack and the method of manufacturing the ferroelectric gate stack in this example is the same as those in Example 1, except that positions of the ferroelectric layer 2 and the resistive switching layer 4 are interchanged.

### Example 6

As shown in FIG. 4, in this example, a planar NMOS field effect transistor is illustrated by way of example in describing the technical solutions of the present disclosure.

The planar NMOS field effect transistor in this example includes a substrate 7 and a ferroelectric gate stack 11 sequentially stacked from bottom to top. The ferroelectric gate stack 11 in this example adopts the ferroelectric gate stack manufactured in Example 1. Left and right sides of the ferroelectric gate stack 11 are both covered by a silicon oxide layer 12 and a silicon nitride layer 13 sequentially. An upper portion of the substrate 7 is provided with a source electrode 8 and a drain electrode 9. An upper surface of the source electrode 8 and an upper surface of the drain electrode 9 are flush with an upper surface of the substrate 7, and the other surfaces of the source electrode 8 and the drain electrode 9 are covered by the substrate 7. A lower surface of the ferroelectric gate stack 11, a lower surface of the silicon oxide layer 12 and a lower surface of the silicon nitride layer 13 cover a portion of the upper surface of the substrate between the source electrode 8 and the drain electrode 9.

The planar NMOS field effect transistor in this example is manufactured by the following method.

In step (a), a silicon substrate is provided.

In step (b), a ferroelectric gate stack 11 is manufactured using the same method as Example 1.

In step (c), a 5 nm silicon oxide layer and a 10 nm silicon nitride layer are sequentially grown on both sides of the ferroelectric gate stack 11.

In step (d), an n-type impurity B is self-aligned injected at a concentration of 1.5×10¹⁹/cm³, annealed to 500° C., and activated, so as to form a source electrode 8 and a drain electrode 9.

### Comparative Example 1

The structure of the ferroelectric gate stack and the method of manufacturing the ferroelectric gate stack in this example are the same as those in Example 1, except that no resistive switching layer 4 is provided.

### Test Example 1

The ferroelectric gate stacks manufactured in Examples 1-5 and Comparative Example 1 are used to manufacture planar NMOS field effect transistors according to the method in Example 6, so as to obtain test samples 1-5 and comparative sample 1, respectively. A pulse of two-thirds of a voltage required for normal switching is applied to the gate, with a pulse width of 1 μs. The number of pulses received by the sample until the accumulation switching occurs is calculated. The greater the number of pulses required, the more difficult the occurrence of switching. No switching is ideal. The test results are shown in Table 1.

TABLE 1

| | Test | Test | Test | Test | Test | Comparative |
|---|---|---|---|---|---|---|
| Groups | sample 1 | sample 2 | sample 3 | sample 4 | sample 5 | sample 1 |
| The number of | 1.05 × 10³ | 1.7 × 10³ | 1.5 × 10³ | 1.3 × 10³ | 1 × 10³ | 20 |
| pulses required | | | | | | |
| for switching | | | | | | |

As shown in Table 1, the number of pulses required for switching of each of the test samples 1-5 is much greater than that of the comparative sample 1, which indicates that the accumulation switching is significantly weakened after the addition of the resistive switching layer 4. The number of pulses required for switching of the test sample 1 is not significantly different from the number of pulses required for switching of the test sample 5, which indicates that the position exchange between the resistive switching layer 4 and the ferroelectric layer 2 has little influence on the results.

The above are just preferred specific embodiments of the present disclosure, and the scope of protection of the present disclosure is not limited to this. Any changes or substitutions that may be easily envisaged by those skilled in the art within the technical scope of the present disclosure should be covered within the scope of protection of the present disclosure.

1. A ferroelectric gate stack, comprising a gate oxygen layer, a thin dielectric layer, and a further gate dielectric layer sequentially stacked from bottom to top;
wherein a ferroelectric layer is further provided between the thin dielectric layer and the gate oxygen layer, and a resistive switching layer is further provided between the thin dielectric layer and the further gate dielectric layer; or
wherein a resistive switching layer is further provided between the thin dielectric layer and the gate oxygen layer, and a ferroelectric layer is further provided between the thin dielectric layer and the further gate dielectric layer.

2. The ferroelectric gate stack according to claim 1, wherein a material of the resistive switching layer comprises one or more of hafnium oxide, silicon oxide, zinc oxide or copper oxide, and a thickness of the resistive switching layer is in a range of 5 nm to 25 nm.

3. The ferroelectric gate stack according to claim 1, wherein a material of the gate oxygen layer comprises silicon oxide or silicon nitride.

4. The ferroelectric gate stack according to claim 3, wherein a thickness of the gate oxygen layer is in a range of 0 nm to 20 nm.

5. The ferroelectric gate stack according to claim 1, wherein a material of the thin dielectric layer comprises alumina.

6. The ferroelectric gate stack according to claim 5, wherein a thickness of the thin dielectric layer is in a range of 1 nm to 5 nm.

7. The ferroelectric gate stack according to claim 1, wherein the ferroelectric layer contains HZO, in which a molar ratio of hafnium oxide to zirconia is in a range of 4:1 to 1:2, and a thickness of the ferroelectric layer is in a range of 5 nm to 15 nm.

8. A ferroelectric field effect transistor, comprising the ferroelectric gate stack of claim 1.

9. The ferroelectric field effect transistor according to claim 8, wherein the ferroelectric field effect transistor comprises a bulk silicon planar transistor, a silicon-on-insulator transistor, a fin transistor, or a gate-all-around transistor.

10. A method of manufacturing the ferroelectric gate stack of claim 1, comprising:
step (1) of providing a substrate and preparing the gate oxygen layer on the substrate;
step (2) of preparing the ferroelectric layer or the resistive switching layer on the gate oxygen layer;
step (3) of preparing the thin dielectric layer on the ferroelectric layer or the resistive switching layer prepared in the step (2);
step (4) of preparing the resistive switching layer or the ferroelectric layer on the thin dielectric layer; and
step (5) of preparing the further gate dielectric layer on the resistive switching layer or the ferroelectric layer prepared in the step (4);
wherein a layer above the thin dielectric layer and a layer below the thin dielectric layer are not simultaneously selected to be ferroelectric layers or not simultaneously selected to be resistive switching layers.
